(19) United States
(12) Patent Application Publication
(10) Pub. No.: US 2019/0093233 A1
(43) Pub. Date: Mar. 28, 2019

(54) Non-Seed Layer Electroless Plating of Ceramic

(71) Applicant: 3D Glass Solutions, Inc, Albuquerque, NM (US)

(72) Inventors: Jeb H. Flemming, Albuquerque, NM (US); Jeff A. Bullington, Albuquerque, NM (US); Sierra D. Jarrett, Albuquerque, NM (US); Timothy J. Mezel, Albuquerque, NM (US)

(21) Appl. No.: 16/140,654

(22) Filed: Sep. 25, 2018

Related U.S. Application Data
(60) Provisional application No. 62/564,073, filed on Sep. 27, 2017.

(51) Int. Cl. C23C 18/16; C23C 18/18; C23C 18/38; C23C 18/42; H01L 23/522; H01L 23/15; H01L 23/498; H01F 17/00; H04B 3/02

(52) U.S. Cl. CPC C23C 18/1639; C23C 18/1605; C23C 18/1865; C23C 18/1868; C23C 18/1875; H04B 3/02; C23C 18/42; H01L 23/5227; H01L 23/15; H01L 23/49827; H01F 17/0006; C23C 18/38

(57) ABSTRACT

A method for fabrication of selectively deposited electroless copper metallization on a photo-definable glass substrate. The electroless copper can metallize a two-dimensional or three-dimensional structure on the photo-definable glass to connect or isolate passive or active devices. The electroless copper metallization can also coat the side walls of aspect ratio blind or through hole via.

### CROSS-REFERENCE TO RELATED APPLICATIONS

This Non-Provisional Patent Application claims priority to U.S. Provisional Patent Application Ser. No. 62/564,073, filed Sep. 27, 2017, the contents of which is incorporated by reference herein in its entirety.

### STATEMENT OF FEDERALLY FUNDED RESEARCH

None.

### TECHNICAL FIELD OF THE INVENTION

The present invention relates to creating a novel copper structure on a photo-definable glass-ceramic using electroless deposition without a deposited conductive seed layer.

### BACKGROUND OF THE INVENTION

Glass and ceramic substrates are insulating and considered impossible to deposit metal using electroplating or electroless plating processes without the use of a deposited conductive seed layer. Conductive seed layers are used to attract the metal ions out of solution on to the substrate in an electroplating process. The seed layers are often deposited by a physical or chemical vapor phase deposition. This invention eliminates the need for a deposited metallic seed layer and allows the direct electroless depositing of copper or silver onto a photo-definable glass ceramic. The electroless deposited layer of copper or silver enables the use of other additive process such as electroplating and electroless plating of other metals.

Electroplating is a process that uses electrical potential to reduce or dissolve metal cations so that they form a coherent metal coating on an electrode. Electroplating on an insulator such as a plastic, glass, and ceramic require the deposition of a seed layer to create a conductive surface that allows electroplate deposition of a conductor on the insulator. The principals of electroplating require a conductive cathode and, as a result, cannot be used to create a metal layer directly on an insulator such as glass or ceramic. In the case of glass or ceramic, a seed layer similar to the initial seed coating is applied. The seed layer is general created by sputter chemical vapor deposition (CVD) or by another similar deposition process. The thin film seed layer is then used as the basis for the continued deposition using traditional electroplating techniques. Electroplating is primarily used to change the surface properties of an object (e.g. abrasion and wear resistance, corrosion protection, conductivity, lubrication, and other surface properties) to create conductive features for the purposes of electronic applications.

Historically, a ceramic or photo-definable material cannot be metallized by electroless plating method requiring the use of deposited conductive seed layer. After a seed layer has been deposited electroless or electroplating can be used to deposit metals such as nickel, silver, gold and copper layers on insulators where the surface of ceramic or glass.

### SUMMARY OF THE INVENTION

Photo-definable glass materials are processed using first generation semiconductor equipment in a simple three step process where the final material can be fashioned into either glass, ceramic, or contain regions of both glass and ceramic. Photo-definable glass has several advantages for the fabrication of a wide variety of microsystems components, systems on a chip and systems in a package. Microstructures and electronic components have been produced relatively inexpensively with these types of glass using conventional semiconductor and printed circuit board (PCB) processing equipment. In general, glass has high temperature stability, combined with, good mechanical and electrically properties, and a better chemical resistance than plastics as well as many types of metals.

Photo-definable glass-ceramics can be converted from the glass phase to a ceramic phase through a combination of ultraviolet light exposure and thermal treatments. Selective application of ultraviolet light using a photo mask, shadow mask, or laser will create regions a ceramic region material in the photo-definable glass when thermally cycled to the glass transition temperature. When exposed to UV-light within the absorption band of cerium oxide, the cerium oxide acts as a sensitizer by absorbing a photon and loosing an electron. This reaction reduce neighboring silver oxide to form silver atoms, e.g.,

Ce³⁺+Ag⁺=Ce⁴⁺+Ag⁰

The silver ions coalesce into silver nano-clusters during the heat treatment process and induce nucleation sites for the formation of a crystalline ceramic phase in the surrounding glass. This heat treatment must be performed at a temperature near the glass transformation temperature. The ceramic crystalline phase is more soluble in etchants, such as hydrofluoric acid (HF), than the unexposed vitreous, amorphous glassy regions. In particular, the crystalline [ceramic] regions of FOTURAN® are etched about 20 times faster than the amorphous regions in 10% HF, enabling microstructures with wall slope ratios of about 20:1 when the exposed regions are removed. See T. R. Dietrich et al., “Fabrication technologies for microsystems utilizing photoetchable glass,” Microelectronic Engineering 30, 497 (1996), which is incorporated herein by reference. Other compositions of photo-definable glass will etch at different rates.

One method of fabricating a metal device using a photosensitive glass substrate—comprised of silica, lithium oxide, aluminum oxide and cerium oxide—involves the use of a mask and UV light to create a pattern with at least one, 2-dimensional or 3-dimensional, ceramic phase region within the photosensitive glass substrate.

This fabrication method involves exposing at least one portion of the photo-definable glass substrate to an activating energy source, heating the photo-definable glass substrate. The photo-definable glass substrate needs to be heated for at least ten minutes above its glass transition temperature, and then cooled to create the ceramic phase. The ceramic regions are lightly etched leaving a residual or partial coating of the ceramic phase that is lithium rich. The lithium rich ceramic region can be metalized with a copper using an electroless deposition process. The electroless deposited copper on the photo-definable glass can be used as an electrical connection from different passive or active devices, individually, as part of a system or to external system level devices. The electroless deposited copper layer can coated with additional metals Ti, Cr, TiW, copper, tungsten, aluminum, silver, gold, nickel palladium using electroplating or electroless plating.

Electroless plating is generally accomplished by using copper sulfate or other copper materials that create anions in the solution. These anions are reduced at the cathode to deposit in the metallic, zero valence state. For example, in an acid solution, copper is oxidized at the anode to Cu²⁺ by losing two electrons. The Cu²⁺ associates with the anion SO₄²⁻ in the solution to form copper sulfate. The Cu²⁺ is reduced to metallic copper at the cathode by gaining two electrons. The result is the effective transfer of copper from the anode source to a plate covering the cathode. In general, this reaction does not occur on glass or ceramic without a seed layer. This invention shows a method to create an electroless deposited copper directly on a ceramic without the requirement of a seed layer.

### BRIEF DESCRIPTION OF THE DRAWINGS

For a more complete understanding of the features and advantages of the present invention, reference is now made to the detailed description of the invention along with the accompanying figures and in which:

FIG. 1 shows the image of the copper electroless plated ceramic/glass composite without a seed layer.

FIG. 2 shows a photo definable glass with nickel plated through glass via with out the use of deposited seed layer.

FIG. 3 shows an example of a device made using the present invention that shows an inductor with irregular metal line spacing and orientation designed in photo-definable glass.

FIGS. 4A and 4B are graphs that show the low loss performance of the inductor in FIG. 3 that rejects losses to parasitics.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims.

The present invention describes an electroless plated copper structure in or on photo-definable glass ceramic media. The photo-definable glass ceramic substrate is a photosensitive glass substrate having a wide number of compositional variations including but not limited to: SiO₂; K₂O; Na₂O; Ag₂O; Au₂O; Cu₂O; B₂O₃; Al₂O₃ Li₂O; and/or CeO₂. Different commercially available forms of photo-definable glass include APEX® Glass and FOTURAN™. APEX® Glass is a registered trademark to 3D Glass Solutions, Inc. and FOTURAN™ is a trademark to Schott, Inc.

The ultraviolet exposed portion of the glass is transformed into a crystalline material by heating the photo-definable glass ceramic substrate to a temperature above the glass transformation temperature. Specifically, the photo-definable glass is exposed to broad spectrum ultraviolet light (about 308-312 nm) at approximately 20 J/cm². The exposed substrate is then baked typically in a two-step process. In the first step, the substrate is heated to a temperature range of 420° C.−520° C. and held for a time frame between 10 minutes and 2 hours—resulting in the coalescing of silver ions into silver nanoparticles—and, in the second step, it is heated to a temperature range of 520° C.−620° C. and held for a time frame between 10 minutes to 120 minutes allowing the lithium oxide to form around the silver nanoparticles. The ceramic phase that forms in the photo-definable glass substrate has an etch rate that is at least 20:1 relative to the glass phase. The photo-definable glass substrate is etched in an etchant, e.g., a hydrofluoric (HF) acid solution, that is typically 5% to 10% by volume. Creating an electroless plated copper metal structure typically requires a light or short duration HF etch surface. The duration is generally less than 10 minutes for surface structures with through glass vias (TGV's), whereas other structures in the photo-definable glass may require longer etch times.

The UV exposure and thermal cycling achieve three fundamental functions that enable the electroless plating of copper or other metals. The UV exposure and thermal annealing of the photo-definable glass enables the diffusion of silver to form clusters that act as a catalyst for the formation of the nanoscale ceramic regions in the photo-definable glass. The nanoscale crystalline ceramic regions that contain lithium metasilicate etch much faster due to the silica rich grain boundaries that are preferentially etched by the HF acid. Second, the surface of the etched photo-definable glass has less silica content and lithium metasilicate. Some of the lithium metasilicate material is exposed on the surface of the etched photo-definable glass. When the etched photo-definable glass substrate is placed into an electroless plating solution of either copper or silver, the lithium metasilicate on the etched surface catalyzes the deposition of metal from the electroless plating solution.

The remaining metallic elements react with the Cu²⁺ and associate with the anion, SO₄²⁻, in the solution to form copper sulfate, CuSO₄. The reaction occurs best at bath or solution temperatures between 30° C. and 85° C. A preferred bath or solution temperature is 50° C. for less than 30 minutes, but the bath or solution temperature and time can be varied in accordance with the needs of the specific device. At this time and temperature, the metal rich regions of the remaining ceramic material react with the copper ions in solution to form metallic copper that has been electrolessly depositioned at heights less than 50 μm and greater than 0.001 μm. Depending on the thickness of the copper, the atmosphere that the copper is exposed to when it is removed from the plating bath and the temperature of the atmosphere, the electroless plated copper may form a copper oxide on the surface or through the entire volume. Copper oxide is an n-type semiconductor and can be treated as a metal when electrically biased. Independent of whether the electrolessly deposited copper is a metal or a metal oxide it can be treated as a metal when electrically biased and used to deposit other metals through an electroplating process. There are a large number of traditional electroplating metals including: gold, copper silver, tin, zinc, copper, cadmium, chromium, nickel, platinum, palladium, lead and others. The use of a photo mask or shadow mask enables the selective exposure of the photo-definable glass and, as such, selective deposition of the electroless copper creating a metallic pattern directly on the ceramic phase of the photo-definable glass with out the use of a seed layer.

Furthermore, the electroless deposited copper or silver may also be used as a seed layer for an additional electroless or electroplating deposition of materials including, but not limited to, palladium, nickel, platinum, silver, and gold.

One embodiment is to accomplish a fully etched ceramic phase leaving only the glass phase of the photo definable glass. In this case, the surface of the remaining photo-definable glass of the feature is exposed to UV radiation at 310 nm and thermal processing above the glass transition temperature. The combination of the UV exposure and thermal treatment creates a ceramic layer on the surface of the previously etched feature. The depth of the ceramic layer is a function of the intensity of the UV light exposure. For example, a 0.25 J exposure results in a ceramic region less than 50 μm in depth. The ceramic layer is then exposed to a dilute acid (5-10% HF) leaving a lithium metasilicate at the surface of the ceramic phase. The photo-definable glass with lithium metasilicate surface is then placed into an electroless plating solution held at 50° C. The temperature (50° C.) electroless plating solution enables the reaction of the metal ions with the lithium metasilicate that nucleates the deposition of metal ions on the surface of the etched, two or three dimensional feature. The electroless solution can be a copper or silver medium. The electroless deposited metal (silver or copper) can be used as an effective intrinsic non-deposited seed layer for an electroplating process.

A second embodiment is to expose a surface of the photo definable glass to UV radiation at 310 nm and thermal processing above the glass transition temperature creating a ceramic layer on the surface to create a thin ceramic region on top of the two or three-dimensional feature. The ceramic layer is exposed to a dilute solvent/acid to expose the lithium metasilicate at the surface. When the lightly etched ceramic is exposed to the electroless plating solution at 50° C., the metal ions from the electroless plating solution are nucleating on the surface. The electroless deposited metal (silver or copper) can be used as an effective seed layer for an electroplating process.

A third embodiment is to expose the photo definable glass to UV radiation at 310 nm at 10 J/cm², that passes through a mask where the mask has a linear pattern of pillars. The photo definable glass is then heated above the glass transition temperature creating the UV light exposed ceramic regions. The photo definable glass is then exposed to a uniform illumination UV radiation at 310 nm at less than 1 J/cm². The photo-definable glass is lightly etched for less than 20 seconds in a dilute HF solution exposing a lithium metasilicate rich region of the ceramic phase of the photo definable glass. When the lightly etched ceramic is exposed to the electroless plating solution at 50° C., the metal ions from the electroless plating solution nucleate on the surface. The electroless deposited metal (silver or copper) can be used as an effective seed layer for an electroplating process. The electroless deposited layer is then used as the electroplating region for additional copper metal deposition. Using a photo mask that has wider line, that is 25% larger than the electroplated copper metal to expose the photo definable glass to UV radiation at 310 nm at 10 J/cm² and then heated above the glass transition temperature converting the UV light exposed of the photo definable glass to ceramic regions. The photo definable glass substrate is the placed into a in a dilute HF solution for at least 5 min leaving copper metal line supported by the small glass pillars. The pillar supported metal line can be used as a low loss transmission line for RF frequencies (0.5 GHz to 100 GHz) or to make a complex inductor. The complex metal is a virtually free-standing inductor that has low loss broad band performance for RF frequencies 0.5 GHz to 100 GHz.

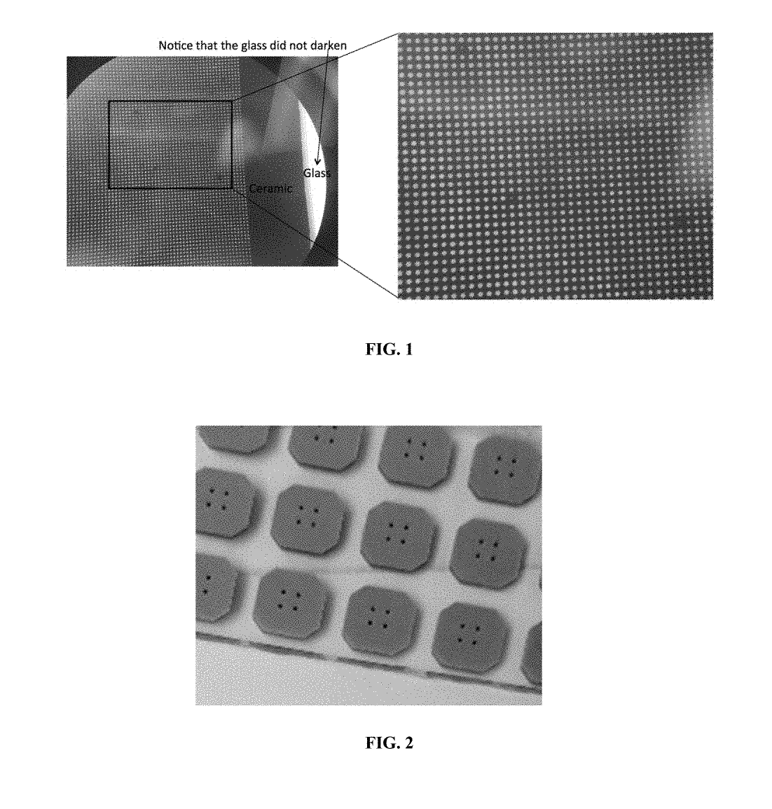

FIG. 1 shows selectively deposited copper on the exposed lithium metasilicate material of the patterned and lightly etched photo-definable glass. In this structure, the copper is deposited around a solid cylinder of the glass phase for the photo-definable glass.

FIG. 2 shows selectively deposited copper on the exposed lithium metasilicate material that is used for a seed layer for the electroplating of a 4 μm layer of nickel. The pattern includes planar surface and through glass via. The surface and through glass via were lightly etched to expose the lithium metasilicate of the photo definable glass. The nickel-palladium electroplated via had an aspect ratio greater than 50 to one. Most deposited seed layers such as a spin on glass with palladium doping have a limitation of an aspect ratio of six to one. With a small aspect ratio, a 1 mm thick photo definable glass has a minimum via diameter of 165 p.m. At a time when the industry is moving to finer geometries the small aspect ratio is unacceptable. A 200 μm thick photo definable glass substrate will allow the 33 μm diameter via with lower device yields due the fragile nature of the photo definable glass substrate. The lithium metasilicate intrinsic seed layer allows for the formation or connection to two-dimensional or three-dimensional structures that are created by electroplating. The electrical connection to or device formation include: interconnects, inductors, capacitors, resistor, transmission line, solder bumps and many others.

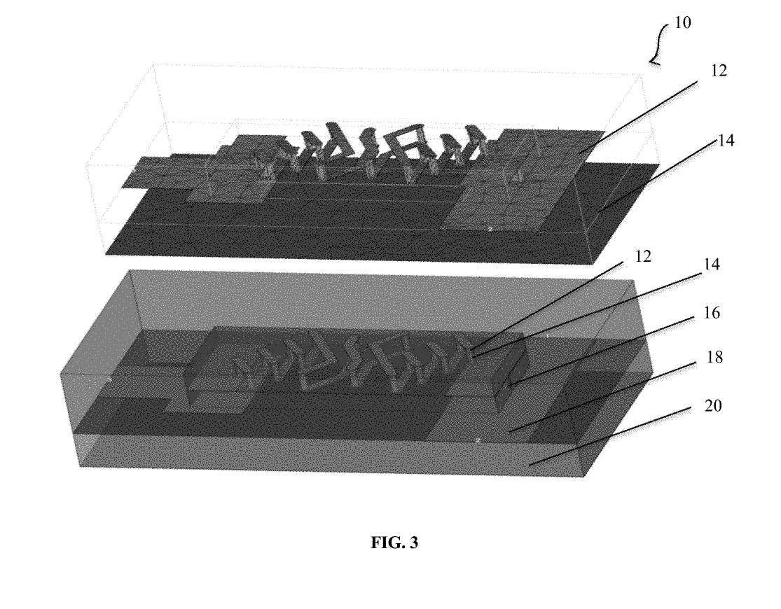

FIG. 3 shows an inductor configuration with non-uniform metal line spacing and orientation that is immune to parasitic losses. The inductor shown in FIG. 3 can be made by using traditional vacuum deposited seed layer or by the intrinsic lithium metasilicate that remains after the light etch of the ceramic regions of the converted photo-definable glass. More particularly, FIG. 3 shows an example of a device 10 made using the present invention that shows an inductor 12 with irregular metal line spacing and orientation designed in photo-definable glass. In the top image, the device 10 made using the present invention that shows the shape of an inductor 12 with irregular metal line spacing and orientation in relation to a plane 14. The lower image shows the device 10 made using the present invention that shows an inductor 12 with irregular metal line spacing and its interconnects made using vias 14 that were formed in layers in the photo-definable glass and connection 16 that contact electrical contacts 18 on a substrate 20.

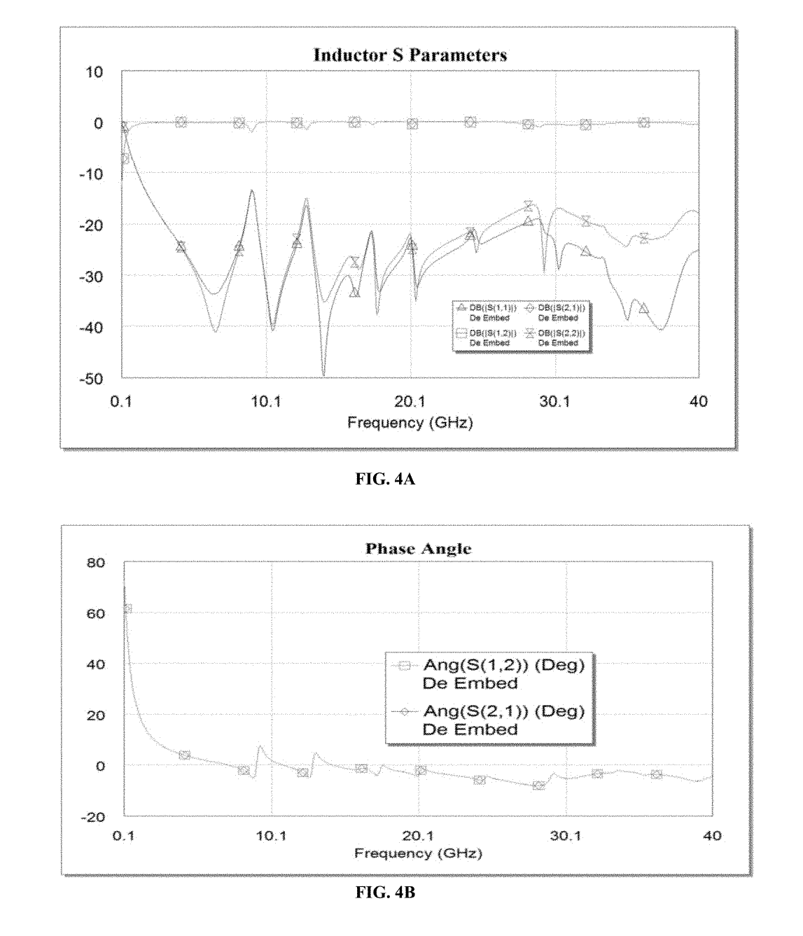

FIGS. 4A and 4B are graphs that show the low loss performance of the inductor in FIG. 3 that rejects losses to parasitics. In FIG. 4A, the graph shows the inductor S parameters versus frequency (GHz) obtained using the present invention. In FIG. 4B, the graph shows the phase angle versus frequency (GHz) obtained using the present invention.

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not restrict the scope of the invention.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), properties(s), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. A method of electroless deposition of metal on a photo-definable glass comprising of:
masking a pattern comprising one or more angles to form a pattern on the photosensitive glass substrate;
exposing at least one portion of the photosensitive glass substrate to an activating UV energy source;
heating the photosensitive glass substrate to a heating phase of at least ten minutes above its glass transition temperature;
cooling the photosensitive glass substrate to transform at least part of the exposed glass to a crystalline material to form a glass-ceramic crystalline substrate;
partial etching away the ceramic phase of the photo-definable glass substrate with an etchant solution to intrinsic seed layer at the surface of layer ceramic phase in the pattern; and
placing the photo-definable glass substrate into an electroless plating bath containing a soluble metal ion that reacts with the etched surface of the definable glass-ceramic substrate and deposits a metal or a semiconducting metal oxide.

2. The method of claim 1, wherein the photo-definable glass substrate is comprised of at least silica, lithium oxide, aluminum oxide, and cerium oxide.

3. The method of claim 1, wherein the etched pattern is a blind via, through glass via, straight line, rectangular, or circular.

4. The method of claim 1, wherein the etched pattern has an aspect ratio greater than 6 to 1.

5. The method of claim 1, wherein the metal ion has a work function less 5.0 eV.

6. The method of claim 1, wherein the metal ion is copper or silver ion.

7. The method of claim 1, wherein the semiconducting metal oxide is copper oxide.

8. The method of claim 1, wherein the active nucleation material seed layer on the etch ceramic is a lithium metasilicate material.

9. The method of claim 1, wherein the electroless plated metal has a thickness of less than 50 μm.

10. The method of claim 1, wherein the electroless plating bath is between 25° C. and 85° C.

11. The method of claim 1, wherein the electroless plated metal is used as a seed layer for electroplating metal on to photo-definable glass.

12. The method of claim 11, wherein the plated metal is Fe, Cu, Au, Ni, In, Ag, Pt, or Pd.

13. The method of claim 1, wherein the electroless plated metal of the intrinsic seed layer is used to make an electrical connection to interconnects, inductors, capacitors, resistor, transmission line, solder bumps or other electronic features.

14. The method of claim 1, wherein the electroless plated metal is used to make an electrical connection too interconnects, inductors, capacitors, resistor, transmission line, solder bumps and many others electronic features.

15. A low loss inductor and transmission line that operates from 0.5 GHz to 100 GHz formed in a photo-definable glass by the method of claim 1.

16. The inductor of claim 15, wherein a low loss inductors operates from 0.01 nh to 70 nh with nominal flat inductance over the designed frequency range formed in a photo-definable glass by the method of claim 1.

17. The inductor of claim 15, wherein the inductor has a non-uniform metal line spacing and orientation that rejects parasitic losses.

18. A low loss inductor and transmission line made by a method of electroless deposition of metal on a photo-definable glass comprising of:
forming at least two electrical contacts and one or more first portions of the low loss inductor and transmission line portions on a substrate;
connecting the low loss inductor and transmission line portions to one or more vias formed by:
masking a pattern comprising one or more first portions of an antenna having one or more angles on the photosensitive glass substrate;
exposing at least one portion of the photosensitive glass substrate to an activating UV energy source;
heating the photosensitive glass substrate to a heating phase of at least ten minutes above its glass transition temperature;
cooling the photosensitive glass substrate to transform at least part of the exposed glass to a crystalline material to form a glass-ceramic crystalline substrate;
partial etch away the ceramic phase of the photo-definable glass substrate with an etchant solution to intrinsic seed layer at the surface of layer ceramic phase in the pattern;
depositing a metal into the one or more vias in the photosensitive glass substrate;
masking a pattern for a second portion of the one or more low loss inductor and transmission line opposite the first portion of the one or more low loss inductor and transmission line portions, wherein the first and second portions are connected by the one or more vias; and
placing the photo-definable glass substrate into an electroless plating bath containing a soluble metal ion that reacts with the etched surface of the definable glass-ceramic substrate and deposits a metal or a semiconducting metal oxide to form the second portion of the one or more low loss inductor and transmission line.

19. The method of claim 18, wherein the electroless plated metal of the intrinsic seed layer is used to make an electrical connection to interconnects, inductors, capacitors, resistor, transmission line, solder bumps or other electronic features.

20. The method of claim 18, wherein the electroless plated metal is used to make an electrical connection too interconnects, inductors, capacitors, resistor, transmission line, solder bumps and many others electronic features.
